(19) United States
(12) Patent Application Publication
(10) Pub. No.: US 2025/0210410 A1
(43) Pub. Date: Jun. 26, 2025

(54) METHOD FOR TRANSFERRING A THIN FILM ONTO A SUPPORT SUBSTRATE

(71) Applicants: Soitec, BERNIN (FR); Commissariat à I'Energie Atomique et aux Énergies Alternatives, Paris (FR)

(72) Inventors: Marianne Coig, Grenoble Cedex 09 (FR); Frédéric Mazen, Grenoble Cedex 09 (FR); Oleg Kononchuk, BERNIN (FR); Didier Landru, BERNIN (FR); Nadia Ben Mohamed, BERNIN (FR)

(21) Appl. No.: 18/852,313

(22) PCT Filed: Mar. 20, 2023
(86) PCT No.: PCT/EP2023/057016

§ 371 Date: Sep. 27, 2024

(30) Foreign Application Priority Data
Apr. 1, 2022 (FR) FR2202978

(51) Int. Cl. H01L 21/762

(52) U.S. Cl. CPC H01L 21/76254

(57) ABSTRACT

A method for transferring a thin film onto a support substrate comprises implanting into a donor substrate light species including co-implantation of hydrogen ions at a first dose and a first implantation energy, and helium ions at a second dose and a second implantation energy. Hydrogen ions are also locally implanted at a third dose and a third energy to form an overdosed local region in a buried fragile plane formed by the implanted ions. The donor substrate and the support substrate are assembled by direct bonding to form a bonded structure, and a fracture heat treatment is applied to the bonded structure so as to induce spontaneous separation along the buried fragile plane. The separation leads to the transfer of a thin film from the donor substrate onto the support substrate. The overdosed local region of the buried fragile plane constitutes a starting point for the separation.

### CROSS-REFERENCE TO RELATED APPLICATIONS

This application is a national phase entry under 35 U.S.C. § 371 of International Patent Application PCT/EP2023/057016, filed Mar. 20, 2023, designating the United States of America and published as International Patent Publication WO 2023/186595 A1 on Oct. 5, 2023, which claims the benefit under Article 8 of the Patent Cooperation Treaty of French Patent Application Serial No. FR2202978, filed Apr. 1, 2022.

### TECHNICAL FIELD

The present disclosure relates to the field of microelectronics and semiconductors. In particular, the present disclosure relates to a method for transferring a thin film onto a support substrate, based on Smart Cut™ technology, the thin film exhibiting improved roughness after separation. In particular, the transfer method can be used to manufacture an SOI structure.

### BACKGROUND

Smart Cut™ technology is well known for manufacturing SOI (silicon-on-insulator) structures and, more generally, for thin-film transfer. This technology is based on the formation of a brittle plane buried in a donor substrate, by implanting light species into the substrate; the buried brittle plane delimits, with a front face of the donor substrate, the thin film to be transferred. The donor substrate and a support substrate are then joined at their respective front faces to form a bonded structure. The assembly is advantageously carried out by direct bonding, by molecular adhesion, that is, without involving adhesive material: a bonding interface is thus established between the two assembled substrates. The growth of microcracks in the buried brittle plane, through thermal activation, can lead to spontaneous separation along the plane, resulting in the transfer of the thin film onto the supporting substrate (forming the stacked structure, for example, SOI type). The remaining donor substrate can be reused for a subsequent film transfer. After separation, it is usual to apply finishing treatments to the stacked structure, to restore the crystalline quality and surface roughness of the transferred thin film. These treatments are known to involve oxidizing or smoothing heat treatments (under neutral or reducing atmospheres), chemical cleaning and/or etching and/or chemical-mechanical polishing steps. Various inspection tools are available to check the entire surface of the thin film.

When separation in the buried brittle plane is spontaneous, significant variability is observed in terms of the surface roughness of the thin film transferred, both at high frequencies (microroughness) and at low frequencies (rippling, local areas of high roughness, mottling, etc.). These variabilities are visible and measurable, in particular, via the aforementioned inspection tools, when checking the thin film in the final structure.

The surface roughness of the thin film after finishing can be mapped using a Surfscan™ inspection tool from KLA-Tencor (FIG. 1A). The level of roughness and potential patterns (mottling, dense zones, etc.) are measured or made apparent by measuring the diffuse background noise (“haze”) corresponding to the intensity of light scattered by the surface of the thin film. The haze signal varies linearly with the square of the RMS surface roughness in the spatial frequency range from 0.1 to 10 μm⁻¹. Please refer to the article “Seeing through the haze,” by F. Holsteyns (Yield Management Solutions, Spring 2004, pp 50-54) for more information on this large-area roughness inspection and evaluation technique.

The maps in FIGS. 1A and 1B show the surface roughness of two thin layers transferred from two bonded structures that are treated identically up to the finish. FIG. 1A shows a peripheral zone of residual roughness, known as the “dense zone” (ZD); FIG. 1B has none at all. More pronounced mottling (M) is also visible in FIG. 1A. Average and maximum roughness (expressed in ppm haze) also differ between FIGS. 1A and 1B. FIGS. 1A and 1B show the variability of the final quality and roughness of thin films, which is mainly due to the variability of surface roughness (high and low frequencies) after separation.

To improve the final quality of the transferred thin films, it is therefore still important to reduce the surface roughness (whatever the spatial frequency) of these layers after transfer, in the case of spontaneous separation by thermal activation.

### BRIEF SUMMARY

The present disclosure proposes a transfer method using a local overdosage of light species in the buried fragile plane of the donor substrate, ensuring early initiation of fracture and obtaining improved roughness over the entire surface of the thin film after separation, to achieve excellent surface quality after the finishing stages of the stacked structure. The method is particularly advantageous for the manufacture of SOI structures.

More particularly, the present disclosure relates to a method for transferring a thin film onto a support substrate, comprising the following steps:
providing a bonded structure comprising a donor substrate and the support substrate, assembled by direct bonding at the respective front faces thereof, following a bonding interface extending along a main plane, the donor substrate comprising a buried fragile plane substantially parallel to the main plane and formed by a step of implanting light species including co-implantation of hydrogen ions at a first dose and a first implantation energy, and of helium ions at a second dose and a second implantation energy,
applying a fracture heat treatment to the bonded structure so as to induce spontaneous separation along the buried fragile plane, linked to the growth of microcracks in the plane by thermal activation, the separation leading to the transfer of a thin film from the donor substrate onto the support substrate.

The process is remarkable in that the step of implanting light species further comprises localized implantation of hydrogen ions with a third dose and a third energy, to form an overdosed local region in the buried fragile plane, the third dose corresponding to more than three times the first dose, so that the overdosed local region constitutes a separation starting point.

According to advantageous features of the present disclosure, taken alone or in any feasible combination:
the third energy is lower than the first energy;
the local overdosed region is located in a central region of the donor substrate, according to the main plane;
the first dose is 1E16/cm²+/−40%, the second dose is 1E16/cm²+/−40%, and the third dose is between three times (excluded) and seven times the first dose, preferably around four times the first dose;
the local overdosed region has a surface area, in the main plane, of between 10 μm² and 2 cm²;
the donor substrate and/or the support substrate have an insulating layer, at least on the respective front side thereof, which forms a buried insulating layer adjacent to the bonding interface in the bonded structure;
the thin film from the donor substrate is monocrystalline silicon and the support substrate comprises monocrystalline silicon, to form a stacked SOI structure.

### BRIEF DESCRIPTION OF THE DRAWINGS

Other features and advantages of the present disclosure will emerge from the following detailed description of example embodiments of the present disclosure with reference to the appended figures, in which:

FIGS. 1A and 1B show two representative surface roughness maps of two transferred thin films, from two bonded structures treated identically until finishing, using a conventional method; both maps were obtained via a Surfscan™ inspection tool;

FIG. 2 shows a graph indicating the surface roughness of thin films as a function of fracture time, for a plurality of bonded structures (of a different type from the bonded structures shown in reference to FIGS. 1A and 1B) treated identically until finishing, according to a conventional method;

FIG. 3 shows a bonded structure used in an intermediate stage of the transfer method according to the present disclosure;

FIG. 4 shows a stacked structure and the remainder of a donor substrate, obtained by a transfer method in accordance with the present disclosure;

FIG. 5 shows different localized hydrogen ion implantation tests and the associated results; and

FIG. 6 shows a photo of a stacked structure obtained by a transfer method in accordance with the present disclosure.

Some figures are schematic depictions, which, for the sake of readability, are not to scale. In particular, the thicknesses of the layers along the z axis are not to scale with respect to the lateral dimensions along the x and y axes.

The same references in the figures or description may be used for elements of the same type.

### DETAILED DESCRIPTION

The present disclosure relates to a method for transferring a thin film onto a support substrate, to form a stacked structure. As mentioned in the introduction, such a stacked structure can be of the SOI type, comprising a thin silicon surface layer, an intermediate insulating layer and a silicon support substrate. The support substrate may optionally comprise other functional layers, such as a charge trapping layer, for example, for SOI structures designed for radio frequency applications. The transfer method described here is not limited to the manufacture of SOI, however, and can be applied to many other stacked structures in the field of microelectronics, microsystems and semiconductors.

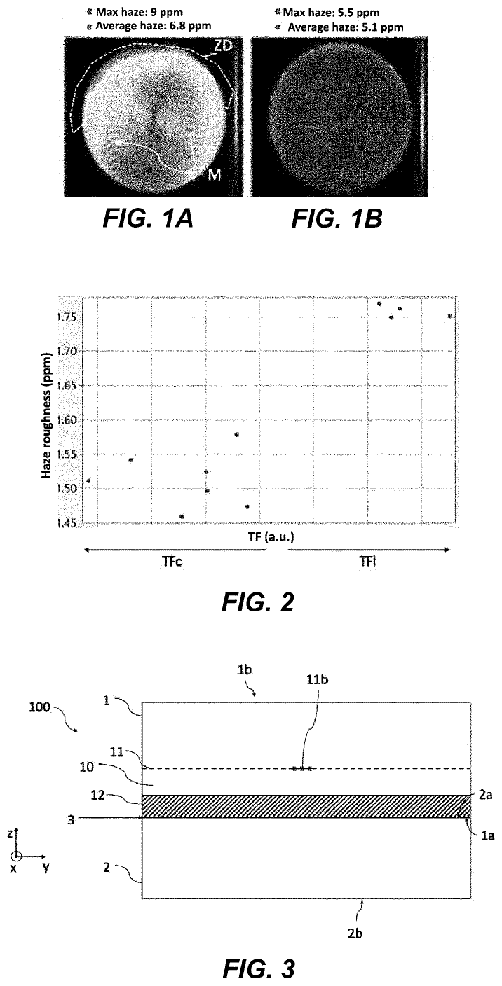

The transfer method according to the present disclosure is based on Smart Cut™ technology. When separation in the buried brittle plane is spontaneous, the fracture time (that is the time after which separation occurs, during thermal fracture annealing) may differ between a plurality of identically treated bonded assemblies, undergoing the same annealing, in the same furnace. The fracture time (TF) depends on a multitude of parameters linked to the formation of the buried fragile plane, the fracture annealing, the nature of the bonded structure, etc. It has been noted that, for similarly prepared bonded structures undergoing the same fracture annealing, separations occurring at short fracture times (TFc) result in thin films having lower high-frequency surface roughness (microroughness) in the final stacked structures (that is after transfer and finishing) than separations occurring at longer fracture times (TF1), as can be seen in FIG. 2. Furthermore, long fracture times induce a local zone of very high roughness (called the dense zone ZD) at the edge of the thin film after fracture, which is not the case or rarely so when the fracture time is short. This dense region degrades the quality and roughness of the thin film, even after finishing, as can be seen in FIG. 1A.

The transfer method according to the present disclosure therefore aims to initiate spontaneous separation in the buried brittle plane in an early (short fracture time) and repeatable (low fracture time dispersion between a plurality of similar bonded structures) manner, so as to substantially improve the surface roughness of the transferred thin film.

To this end, the transfer method comprises firstly providing a bonded structure 100 comprising a donor substrate 1 and the support substrate 2, assembled by direct bonding at the respective front faces (1a, 2a) thereof, following a bonding interface 3 (FIG. 3).

The donor substrate 1 is preferably in the form of a wafer with a diameter of 100 mm, 150 mm, 200 mm, 300 mm or even 450 mm, and with a thickness typically between 300 μm and 1 mm. It comprises a front face 1a and a rear face 1b. The surface roughness of the front face 1a is chosen to be less than 1.0 nm RMS, preferably even less than 0.5 nm RMS (measured by atomic force microscopy (AFM), for example, on a 20 μm×20 μm scan). The donor substrate 1 can be made of silicon or any other semiconductor or insulating material for which thin film transfer may be of interest (for example, SiC, GaN, LiTaO₃, etc.).

It should also be noted that the donor substrate 1 may comprise one or more additional layers 12, at least on its front face 1a, such as an insulating layer. This additional layer can be from a few nanometers to several hundred nanometers thick. As shown in FIG. 3, this additional layer 12 becomes a buried intermediate layer in the bonded structure 100, after assembling the donor substrate 1 and the support substrate 2.

The donor substrate 1 comprises a buried fragile plane 11, which delimits a thin film 10 to be transferred. As is well known with reference to Smart Cut™ technology, such a buried fragile plane 11 can be formed by a step of implanting light species. The light species are implanted at a determined depth in the donor substrate 1, consistent with the thickness of the targeted thin film 10. They will form, around the determined depth, microcavities distributed in a thin film substantially parallel to the front face 1a of the donor substrate 1, or parallel to the plane (x,y) in the figures. This thin film is called the buried fragile plane 11, for simplicity's sake.

In particular, in the context of the present disclosure, the implantation step comprises the co-implantation of hydrogen ions with a first dose and a first implantation energy, and helium ions with a second dose and a second implantation energy.

The implantation energy of the light species is chosen so as to reach the determined depth. For example, hydrogen ions will be implanted at a first energy of between 10 keV and 180 keV, and the helium ions at a second energy of between 20 keV and 210 keV to delimit a thin film 10 having a thickness on the order of 100 nm to 1200 nm.

The implanted hydrogen ion dose (or first dose) is typically 1E16/cm²+/−40% within the stated range of first implant energy. The implanted helium ion dose (or second dose) is also on the order of 1E16/cm²+/−40%, within the stated range of second implant energy.

Advantageously, the helium ions are implanted before hydrogen ions.

Recall that an additional layer may be deposited on the front face 1a of the donor substrate 1, prior to the ion implantation step. This additional layer may be composed of a material such as silicon oxide or silicon nitride, for example. It may be retained for the next assembly step (and form all or part of the intermediate layer of the bonded structure 100), or it may be removed.

The support substrate 2 is also preferably in the form of a wafer with a diameter of 100 mm, 150 mm, 200 mm, 300 mm or even 450 mm, and with a thickness typically between 300 μm and 1 mm. It comprises a front face 2a and a rear face 2b. The surface roughness of the front face 2a is chosen to be less than 1.0 nm RMS, preferably even less than 0.5 nm RMS (measured by AFM, for example, on a 20 μm×20 μm scan). The support substrate 2 can be made of silicon or any other semiconducting or insulating material, for which thin-film transfer may be of interest. In the context of the present disclosure, the material(s) making up the support substrate 2 must be compatible with applying temperatures greater than or equal to 400° C. to the bonded structure 100 resulting from the assembly of the donor substrate 1 and the support substrate 2.

It should also be noted that the support substrate 2 may comprise one or more additional layers, at least on its front face 2a, for example, an insulating and/or charge-trapping layer. The additional layer(s) may have a thickness ranging from a few nanometers to several micrometers. They are buried in the bonded structure 100, after assembling the donor substrate 1 and the support substrate 2.

The assembly between the donor substrate 1 and the support substrate 2 is based on direct bonding by molecular adhesion. As is well known per se, such bonding does not require an adhesive material, as atomic-scale bonds are established between the joined surfaces, forming the bonding interface 3. Several types of molecular adhesion bonding exist, which differ, in particular, by their temperature, pressure, atmosphere conditions or treatments prior to contacting the surfaces. Mention may be made of bonding at room temperature with or without prior plasma activation of the surfaces to be assembled, atomic diffusion bonding (ADB), surface-activated bonding (SAB), etc.

The assembly step may comprise, prior to the contacting of the front faces 1a, 2a to be assembled, conventional chemical cleaning sequences (for example, RCA cleaning), surface activation (for example, oxygen or nitrogen plasma) or other surface preparations (such as cleaning by scrubbing), capable of promoting the quality of the bonding interface 3 (few defects, strong adhesion energy).

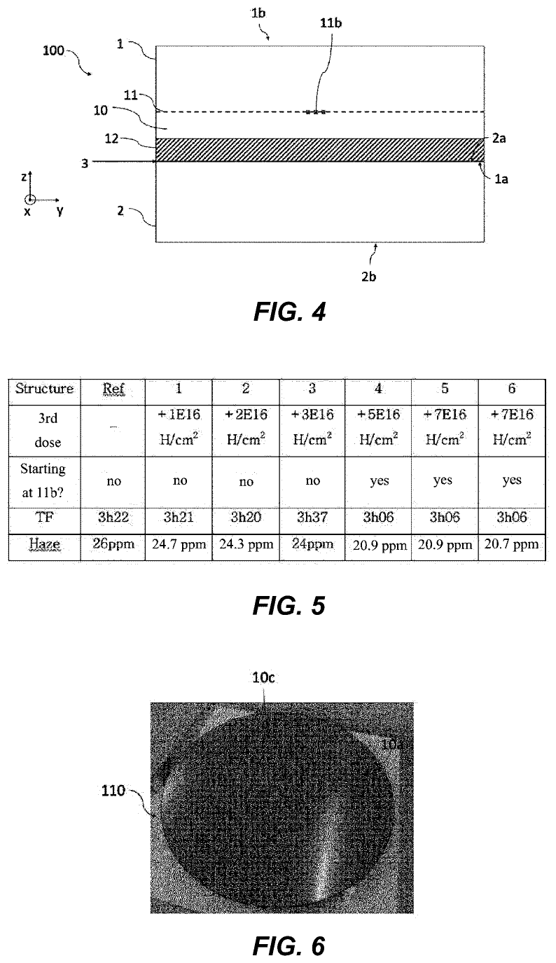

Once the bonded structure 100 has been formed, the transfer method according to the present disclosure involves applying a fracture heat treatment to induce spontaneous separation along the buried fragile plane 11. Separation leads to the transfer of the thin film 10 from the donor substrate 1 to the support substrate 2, to form the stacked structure 110 (FIG. 4). The remainder 1′ of the donor substrate is also obtained. Heat treatment can typically be carried out in a horizontal furnace (capable of treating a plurality of bonded structures 100, collectively), at a temperature of between 200° C. and 400° C., particularly for a silicon-based bonded structure 100.

As previously stated, the step of implanting light species, applied to the donor substrate 1 to form the buried fragile plane 11, comprises the co-implantation of hydrogen ions with a first dose and a first implantation energy, and helium ions with a second dose and a second implantation energy. For example, starting from a silicon donor substrate 1 with a diameter of 300 mm, from which a 240 nm thin film 10 is to be taken, to form an FD-SOI (fully depleted SOI) stacked structure 110, the co-implantation conditions are as follows: introduction of helium ions at 40 keV-1E16/cm², then introduction of hydrogen ions at 25 keV-1E16/cm². An additional layer 12 of silicon oxide is applied to the donor substrate 1, for example, with a thickness of around 100 nm.

These co-implantation conditions, applied to a plurality of structures, can lead to varied results in terms of surface roughness after separation (and after finishing), as explained with reference to FIG. 2, due to a transfer time that is more or less short or long and, in any case, unpredictable.

Thus, to address this problem of transfer time reproducibility, the method according to the present disclosure provides that the step of implanting light species comprises, after or before the co-implantation of helium and hydrogen, a localized implantation of hydrogen ions with a third dose and a third energy. This implantation creates a local overdosed region 11b in the buried fragile plane 11, which is intended as a starting point for early separation in the buried fragile plane 11. Such early separation ensures short fracture times and consequently an excellent, highly reproducible surface finish of the transferred thin film 10 during collective processing of a plurality of bonded structures 100.

This localized implantation is remarkable in that the third dose corresponds to more than three times the first dose, which is very significant. In fact, it has been noticed that it is not enough to locally implant the first dose of hydrogen once, twice or even three times to form a reliable and reproducible starting point for separation. When the third dose does not exceed three times the first dose, the local overdosed region 11b does not repeatedly induce the starting of separation: this maintains significant variability in terms of fracture time and therefore undesirable fluctuations in the surface state of the transferred thin film 10. Indeed, contrary to all expectations, a third dose less than or equal to three times the first dose is not sufficient to initiate a fracture in the buried fragile plane 11, before other potential starting points: that is, localized bonding defects at the bonding interface 3 or the unbonded peripheral edge region of the bonded structure 100.

The table in FIG. 5 shows fracture time and post-separation surface finish results (in ppm haze) for various localized hydrogen ion implantation tests, in the case of a buried fragile plane 11 formed by co-implantation of helium and hydrogen at energies of 40 keV and 25 keV, respectively, and at doses of 1E16/cm² and 1E16/cm², respectively. The hydrogen ion implantation energy (or third energy) in the local overdosed region 11b is 25 keV, identical to the first implantation energy. Separation annealing is carried out at 350° C.

These results confirm that overdoses less than or equal to three times the first dose (H) do not have the desired effect of early separation initiation, contrary to what might have been expected. The fracture time for structures 1 to 3 remains high and fluctuates, and the surface finish has not improved on the usual values (“Ref” structure) obtained without local overdosing (“haze” at around 26 ppm+/−2 ppm).

When the third hydrogen dose of localized implantation is equal to five times (structure 4) or even seven times (structures 5, 6) the first dose, the local overdosed region 11b acts effectively as a fracture starting point: it induces shorter, reproducible fracture times and improves surface finish in terms of repeatability and haze amplitude (12% to 25% reduction compared to structures without local overdosed region 11b). Early fracture ensures low microroughness (high spatial frequency) and few, if any, local regions of high roughness (otherwise known as dense regions ZD).

It should also be noted that the local surface roughness of the thin film 10, at the level of the local overdosed region 11b, is lower than in the other regions of the thin film 10, and therefore does not generate a particular signature, which could affect the quality of the final stacked structure 110. For example, for structures 5 and 6 shown in FIG. 5, the haze value is on the order of 19 ppm (compared to 20.9 or 20.7 ppm, overall on the plate).

Preferably, with a first dose (H) of 1E16/cm²+/−40%, the third dose is strictly greater than three times the first dose and less than or equal to seven times the first dose; even more preferably, the third dose is between four and five times the first dose.

This particular overdose selection has been identified as extremely effective in forming an early and reproducible fracture starting point.

Beyond the upper limit of seven times the first dose, there is a significant risk of blistering on the surface of donor substrate 1. The presence of these blisters then causes bonding defects at the bonding interface 3 and degrades the quality of the bonded structure 100.

The local overdosed region 11b can be located in the center of the donor substrate 1 (along the main plane (x,y)), at the periphery or in an intermediate region between these two extremes. Centrally located, it brings the advantage of propagation of the separation wave from the center to the edges of the bonded structure 100, which greatly limits the amplitude of mottling M or other fracture waves (roughness and low-frequency ripples) on the surface of the transferred thin film 10.

The local overdosed region 11b can occupy an area, in the main (x,y) plane, of between a few tens of μm² and a few cm², typically between 10 μm² and 2 cm².

Localized implantation can be performed through a mechanical mask featuring a hole whose surface area is equal to that targeted for the local overdosed region 11b. Alternatively, it can be carried out using masking techniques such as deposition, lithography and etching of screen layers, or by controlled scanning of the hydrogen ion beam.

Finally, advantageously, the localized implantation of hydrogen ions is carried out at a third energy different from the first energy. In fact, it has been shown that the thickness of thin film 10 transferred in region 10c corresponding to the local overdosed region 11b was greater than the thickness of thin film 10 everywhere else. The third implantation energy (relating to the localized implantation of H) is therefore preferably chosen to be lower than the first energy.

To illustrate, FIG. 6 shows a photo of a stacked 110 type stacked structure (similar to structure 5 or 6 in FIG. 5). The visible surface is the free surface 10a of the thin film 10 after transfer. Region 10c (corresponding to the local overdosed region 11b) appears different in color from the rest of the thin film 10, due to the difference in thickness of the thin film 10, locally in region 10c. In this example, the difference in thickness of thin film 10 between region 10c and the rest of the plate is on the order of 29 nm. In the range of implantation energies implemented in these examples, it can be estimated that each keV adds around 8 to 8.5 nm of transferred silicon thin film 10. In the example shown in FIG. 6, the third implantation energy is therefore preferably set lower than the first implantation energy of 3.5 keV, that is, 36.5 keV.

By avoiding a local difference in thickness in region 10c, adjusting the third implantation energy further improves the surface finish of thin film 10 after transfer.

The transfer process according to the present disclosure, due to the presence of the particular local overdosed region 11b, which acts as an early separation starting point in an efficient and reproducible way, provides an improved free surface 10a quality of the transferred thin film 10 compared to an SOI structure obtained from a bonded structure treated by a conventional process, as the free surface 10a presents no or very few mottles M or dense regions ZD. The level of microroughness (“haze”) of the face of a thin film 10 before or after smoothing is also lower than the level of roughness obtained by a conventional method.

Another important advantage is the reproducibility of these results on a plurality of bonded structures 100, processed collectively.

Of course, the present disclosure is not limited to the described embodiments and variant embodiments may be envisaged without departing from the scope of the invention as defined by the claims.

1. A method for transferring a thin film onto a support substrate, the method comprising:
providing a bonded structure comprising a donor substrate and the support substrate, assembled by direct bonding at the respective front faces thereof, following a bonding interface extending along a main plane, the donor substrate comprising a buried fragile plane substantially parallel to the main plane and formed by implanting light species including co-implantation of hydrogen ions at a first dose and a first implantation energy, and of helium ions at a second dose and a second implantation energy;
applying a fracture heat treatment to the bonded structure so as to induce spontaneous separation along the buried fragile plane, linked to a growth of microcracks in the buried fragile plane by thermal activation, the separation leading to the transfer of the thin film from the donor substrate onto the support substrate;
wherein the implanting of the light species further comprises localized implantation of hydrogen ions at a third dose and a third energy so as to form a local overdosed region in the buried fragile plane, the third dose corresponding to more than three times the first dose such that the overdosed local region constitutes a separation starting point.

2. The method of claim 1, wherein the third energy is less than the first energy.

3. The method of claim 2, wherein the local overdosed region is located in a central region of the donor substrate, along the main plane.

4. The method of claim 3, wherein the first dose is 1E16/cm²+/−40%, the second dose is 1E16/cm²+/−40%, and the third dose is between three times (exclusive) and seven times the first dose.

5. The method of claim 4, wherein the local overdosed region has a surface area, in the main plane, of between 10 μm² and 2 cm².

6. The method of claim 5, wherein the donor substrate and/or the support substrate have an insulating layer, at least on a side of their respective front face, which forms a buried insulating, layer adjacent to the bonding interface, in the bonded structure.

7. The method of claim 6, wherein the thin film from the donor substrate comprises monocrystalline silicon, and the support substrate comprises monocrystalline silicon.

8. The method of claim 1, wherein the local overdosed region is located in a central region of the donor substrate, along the main plane.

9. The method of claim 1, wherein the first dose is 1E16/cm²+/−40%, the second dose is 1E16/cm²+/−40%, and the third dose is between three times and seven times the first dose.

10. The method of claim 1, wherein the local overdosed region has a surface area, in the main plane, of between 10 μm² and 2 cm².

11. The method of claim 1, wherein the donor substrate and/or the support substrate have an insulating layer, at least on a side of their respective front face, which forms a buried insulating layer adjacent to the bonding interface in the bonded structure.

12. The method of claim 11, wherein the thin film from the donor substrate comprises monocrystalline silicon, and the support substrate comprises monocrystalline silicon.

13. A method for transferring a thin film onto a support substrate, the method comprising:
implanting ions into a donor substrate to form a buried fragile plane within the donor substrate, including:
implanting hydrogen ions at a first dose and a first implantation energy into a donor substrate;
implanting helium ions at a second dose and a second implantation energy into the donor substrate;
locally implanting hydrogen ions at a third dose and a third energy so as to form a local overdosed region in the buried fragile plane, the third dose being more than three times the first dose;
bonding the donor substrate to a support substrate to form a bonded structure by direct molecular bonding along a bonding interface substantially parallel to the buried fragile plane; and
applying a fracture heat treatment to the bonded structure so as to induce spontaneous separation along the buried fragile plane, the overdosed local region in the buried fragile plane constituting a separation starting point, the separation leading to the transfer of the thin film from the donor substrate onto the support substrate.

14. The method of claim 13, wherein the local overdosed region is located in a central region of the donor substrate.

15. The method of claim 13, wherein the first dose is 1E16/cm²+/−40%, the second dose is 1E16/cm²+/−40%, and the third dose is between three times and seven times the first dose.

16. The method of claim 13, wherein the local overdosed region has a surface area, in the buried fragile plane, of between 10 μm² and 2 cm².

17. The method of claim 13, wherein the donor substrate and/or the support substrate have an insulating layer forming a buried insulating layer adjacent to the bonding interface in the bonded structure.

18. The method of claim 17, wherein the thin film from the donor substrate comprises monocrystalline silicon, and the support substrate comprises monocrystalline silicon.
